(19) United States
(12) Patent Application Publication
(10) Pub. No.: US 2026/0105970 A1
(43) Pub. Date: Apr. 16, 2026

(54) Read Operations in Memory Devices

(71) Applicant: Yangtze Memory Technologies Co., Ltd., Wuhan (CN)

(72) Inventors: Xufeng ZHOU, Wuhan (CN); Zhipeng DONG, Wuhan (CN); Jianjie LI, Wuhan (CN); Weijun WAN, Wuhan (CN); Wei HUANG, Wuhan (CN); Qianru LI, Wuhan (CN)

(21) Appl. No.: 18/932,907

(22) Filed: Oct. 31, 2024

(30) Foreign Application Priority Data
Oct. 12, 2024 (CN) 202411427878.3

(51) Int. Cl. G11C 16/26; G11C 16/04; G11C 16/08

(52) U.S. Cl. CPC G11C 16/26; G11C 16/0483; G11C 16/08

(57) ABSTRACT

Example memory devices, systems, and methods for performing read operations in memory devices are disclosed. One example method includes applying a first voltage of multiple voltages to a word line coupled to a memory cell in a memory cell array. Voltages of a bit line coupled to the memory cell are sensed at multiple time instances. Multiple pieces of estimated data of the memory cell corresponding to the multiple time instances are obtained based on the voltages of the bit line. A first piece of data corresponding to the first voltage is selected from the multiple pieces of estimated data.

### CROSS-REFERENCE TO RELATED APPLICATIONS

This application claims priority to Chinese Patent Application No. 202411427878.3, filed on Oct. 12, 2024, which is hereby incorporated by reference in its entirety.

### TECHNICAL FIELD

The present disclosure relates to memory devices, systems, and methods for performing read operations in memory devices.

### BACKGROUND

Flash memory is a low-cost, high-density, nonvolatile solid-state storage medium that can be electrically erased and reprogrammed. Flash memory includes NOR flash memory and NAND flash memory. Various operations can be performed by a flash memory, for example, read operations, to read data stored in memory cells of the flash memory. For NAND flash memory, a read operation can be performed at the page level.

### SUMMARY

The present disclosure relates to memory devices, systems, and methods for performing read operations in memory devices.

Certain aspects of the subject matter described here can be implemented as a memory device. The memory device includes a memory cell array and a peripheral circuit coupled to the memory cell array and configured to perform operations including applying a first voltage of multiple voltages to a word line coupled to a memory cell in a memory cell array. Voltages of a bit line coupled to the memory cell are sensed at multiple time instances. Multiple pieces of estimated data of the memory cell corresponding to the multiple time instances are obtained based on the voltages of the bit line. A first piece of data corresponding to the first voltage is selected from the multiple pieces of estimated data.

The memory device can include one or more of the following features.

In some implementations, selecting the first piece of data corresponding to the first voltage from the multiple pieces of estimated data includes determining a total number of first memory cells in the memory cell array, and selecting, based on a comparison of the total number of first memory cells to one or more thresholds, the first piece of data corresponding to the first voltage from the multiple pieces of estimated data.

In some implementations, a threshold voltage of each of the first memory cells is larger than a first effective read voltage of multiple effective read voltages of the memory cell, and the multiple pieces of estimated data correspond to the multiple effective read voltages of the memory cell.

In some implementations, the memory cell is a triple-level cell (TLC) or a quad-level cell (QLC), and the first voltage is a read voltage corresponding to a highest threshold voltage range of the memory cell.

In some implementations, the memory cell is a TLC, the first effective read voltage includes the first voltage, the multiple effective read voltages include a second effective read voltage lower than the first voltage and a third effective read voltage higher than the first voltage, and selecting the first piece of data includes: in response to determining that the total number of first memory cells is smaller than a first threshold of the one or more thresholds, selecting, as the first piece of data, a piece of the estimated data corresponding to the second effective read voltage, where the first threshold is smaller than one-eighth of a total number of all memory cells in the memory cell array; in response to determining that the total number of first memory cells is larger than a second threshold of the one or more thresholds, selecting, as the first piece of data, a piece of the estimated data corresponding to the third effective read voltage, where the second threshold is larger than one-eighth of the total number of all memory cells in the memory cell array; or in response to determining that the total number of first memory cells is larger than the first threshold and smaller than the second threshold, selecting, as the first piece of data, a piece of the estimated data corresponding to the first voltage.

In some implementations, the first threshold is smaller than the second threshold.

In some implementations, the first effective read voltage is smaller than the first voltage, the threshold voltage of each of the first memory cells is smaller than the first voltage, the multiple effective read voltages further include the first voltage and a second effective read voltage larger than the first voltage, and selecting the first piece of data includes: in response to determining that the total number of first memory cells is smaller than a third threshold of the one or more thresholds, selecting, as the first piece of data, a piece of the estimated data corresponding to the first effective read voltage, where the third threshold is a total number of second memory cells in the memory cell array, and a threshold voltage of each of the second memory cells is larger than the first voltage and smaller than the second effective read voltage; in response to determining that the total number of first memory cells is larger than the third threshold, selecting, as the first piece of data, a piece of the estimated data corresponding to the second effective read voltage; or in response to determining that the total number of first memory cells is the same as the third threshold, selecting, as the first piece of data, a piece of the estimated data corresponding to the first voltage.

In some implementations, the first effective read voltage is smaller than the first voltage, the multiple effective read voltages further include the first voltage, the threshold voltage of each of the first memory cells is smaller than the first voltage and is larger than the first effective read voltage, and selecting the first piece of data includes: in response to determining that the total number of first memory cells is smaller than a fourth threshold of the one or more thresholds, selecting, as the first piece of data, a piece of the estimated data corresponding to the first voltage; or in response to determining that the total number of first memory cells is larger than the fourth threshold, selecting, as the first piece of data, a piece of the estimated data corresponding to the first effective read voltage.

In some implementations, sensing the voltages of the bit line at the multiple time instances includes a three-strobe sensing, and the three-strobe sensing includes sensing, at a first time instance of the multiple time instances and as a first sensed voltage, the voltages of the bit line; sensing, at a second time instance of the multiple time instances and as a second sensed voltage, the voltages of the bit line, where the second sensed voltage is lower than the first sensed voltage; and sensing, at a third time instance of the multiple time instances and as a third sensed voltage, the voltages of the bit line, where the third sensed voltage is lower than the second sensed voltage.

In some implementations, the read operation is a default read operation performed after a beginning of life (BOL) phase of the memory cell or an end of life (EOL) phase of the memory cell.

In some implementations, the read operation includes a first read operation of the memory cell and a second read operation of the memory cell, the first read operation includes selecting the first piece of data, the second read operation includes selecting a second piece of data, and the read operation further includes outputting data stored in the memory cell based on the first piece of data and the second piece of data.

Certain aspects of the subject matter described here can be implemented as a method. The method includes applying a first voltage of multiple voltages to a word line coupled to a memory cell in a memory cell array. Voltages of a bit line coupled to the memory cell are sensed at multiple time instances. Multiple pieces of estimated data of the memory cell corresponding to the multiple time instances are obtained based on the voltages of the bit line. A first piece of data corresponding to the first voltage is selected from the multiple pieces of estimated data.

The method can include one or more of the following features.

In some implementations, selecting the first piece of data corresponding to the first voltage from the multiple pieces of estimated data includes determining a total number of first memory cells in the memory cell array, and selecting, based on a comparison of the total number of first memory cells to one or more thresholds, the first piece of data corresponding to the first voltage from the multiple pieces of estimated data.

In some implementations, a threshold voltage of each of the first memory cells is larger than a first effective read voltage of multiple effective read voltages of the memory cell, and the multiple pieces of estimated data correspond to the multiple effective read voltages of the memory cell.

In some implementations, the memory cell is a triple-level cell (TLC) or a quad-level cell (QLC), and the first voltage is a read voltage corresponding to a highest threshold voltage range of the memory cell.

In some implementations, the memory cell is a TLC, the first effective read voltage includes the first voltage, the multiple effective read voltages include a second effective read voltage lower than the first voltage and a third effective read voltage higher than the first voltage, and selecting the first piece of data includes: in response to determining that the total number of first memory cells is smaller than a first threshold of the one or more thresholds, selecting, as the first piece of data, a piece of the estimated data corresponding to the second effective read voltage, where the first threshold is smaller than one-eighth of a total number of all memory cells in the memory cell array; in response to determining that the total number of first memory cells is larger than a second threshold of the one or more thresholds, selecting, as the first piece of data, a piece of the estimated data corresponding to the third effective read voltage, where the second threshold is larger than one-eighth of the total number of all memory cells in the memory cell array; or in response to determining that the total number of first memory cells is larger than the first threshold and smaller than the second threshold, selecting, as the first piece of data, a piece of the estimated data corresponding to the first voltage.

In some implementations, the first threshold is smaller than the second threshold.

In some implementations, the first effective read voltage is smaller than the first voltage, the threshold voltage of each of the first memory cells is smaller than the first voltage, the multiple effective read voltages further include the first voltage and a second effective read voltage larger than the first voltage, and selecting the first piece of data includes: in response to determining that the total number of first memory cells is smaller than a third threshold of the one or more thresholds, selecting, as the first piece of data, a piece of the estimated data corresponding to the first effective read voltage, where the third threshold is a total number of second memory cells in the memory cell array, and a threshold voltage of each of the second memory cells is larger than the first voltage and smaller than the second effective read voltage; in response to determining that the total number of first memory cells is larger than the third threshold, selecting, as the first piece of data, a piece of the estimated data corresponding to the second effective read voltage; or in response to determining that the total number of first memory cells is the same as the third threshold, selecting, as the first piece of data, a piece of the estimated data corresponding to the first voltage.

In some implementations, the first effective read voltage is smaller than the first voltage, the multiple effective read voltages further include the first voltage, the threshold voltage of each of the first memory cells is smaller than the first voltage and is larger than the first effective read voltage, and selecting the first piece of data includes: in response to determining that the total number of first memory cells is smaller than a fourth threshold of the one or more thresholds, selecting, as the first piece of data, a piece of the estimated data corresponding to the first voltage; or in response to determining that the total number of first memory cells is larger than the fourth threshold, selecting, as the first piece of data, a piece of the estimated data corresponding to the first effective read voltage.

In some implementations, sensing the voltages of the bit line at the multiple time instances includes a three-strobe sensing, and the three-strobe sensing includes sensing, at a first time instance of the multiple time instances and as a first sensed voltage, the voltages of the bit line; sensing, at a second time instance of the multiple time instances and as a second sensed voltage, the voltages of the bit line, where the second sensed voltage is lower than the first sensed voltage; and sensing, at a third time instance of the multiple time instances and as a third sensed voltage, the voltages of the bit line, where the third sensed voltage is lower than the second sensed voltage.

In some implementations, the read operation is a default read operation performed after a beginning of life (BOL) phase of the memory cell or an end of life (EOL) phase of the memory cell.

In some implementations, the read operation includes a first read operation of the memory cell and a second read operation of the memory cell, the first read operation includes selecting the first piece of data, the second read operation includes selecting a second piece of data, and the read operation further includes outputting data stored in the memory cell based on the first piece of data and the second piece of data.

Certain aspects of the subject matter described here can be implemented as a memory system. The memory system includes a memory device and a controller coupled to the memory device and configured to initiate operations. The memory device includes a memory cell array and a peripheral circuit coupled to the memory cell array and configured to perform the operations including applying a first voltage of multiple voltages to a word line coupled to a memory cell in a memory cell array. Voltages of a bit line coupled to the memory cell are sensed at multiple time instances. Multiple pieces of estimated data of the memory cell corresponding to the multiple time instances are obtained based on the voltages of the bit line. A first piece of data corresponding to the first voltage is selected from the multiple pieces of estimated data.

The details of these and other aspects and implementations of the present disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 illustrates an example of a schematic circuit diagram of a memory device including peripheral circuits, according to some aspects of the present disclosure.

FIG. 2 illustrates an example of a side view of cross-sections of a memory cell array including NAND memory strings, according to some aspects of the present disclosure.

FIG. 3 illustrates an example memory device that includes some example peripheral circuits and a memory cell array, according to some aspects of the present disclosure.

FIG. 4 illustrates a detailed block diagram of an example structure of a page buffer, according to some aspects of the present disclosure.

FIG. 5 illustrates example threshold voltage distributions of a triple-level memory cell (TLC), according to some aspects of the present disclosure.

FIG. 6 illustrates example threshold voltage distributions of a quad-level memory cell (QLC), according to some aspects of the present disclosure.

FIG. 7 illustrates an example of using effective read voltages during a read operation of a memory cell in a memory cell array, according to some aspects of the present disclosure.

FIG. 8 illustrates a second example of using effective read voltages during a read operation of a memory cell in a memory cell array, according to some aspects of the present disclosure.

FIG. 9 illustrates an example workflow of performing a read operation of a memory cell in a memory cell array, according to some aspects of the present disclosure.

FIG. 10 illustrates example word line voltage and sensing node (SO) voltage during a read operation of a memory cell in a memory cell array, according to some aspects of the present disclosure.

FIG. 11 illustrates a third example of using effective read voltages during a read operation of a memory cell in a memory cell array, according to some aspects of the present disclosure.

FIG. 12 illustrates a fourth example of using effective read voltages during a read operation of a memory cell in a memory cell array, according to some aspects of the present disclosure.

FIG. 13 is a flow chart of an example process for reducing verify operation time in a memory device, according to some aspects of the present disclosure.

FIG. 14 illustrates a block diagram of an example system having a memory device, according to some aspects of the present disclosure.

FIG. 15A illustrates a diagram of a memory card having a memory device, according to some aspects of the present disclosure.

FIG. 15B illustrates a diagram of a solid-state drive (SSD) having a memory device, according to some aspects of the present disclosure.

Like reference numbers and designations in the various drawings indicate like elements.

### DETAILED DESCRIPTION

Memory devices, such as NAND flash memory devices, can store more than a single bit of information into each memory cell in multiple levels (i.e., states) in order to increase the storage capacity and reduce the cost per bit. For example, data may be programmed (written) into memory cells having multiple levels (xLCs), such as multi-level cells (MLCs), triple-level cells (TLCs), and quad-level cells (QLCs).

Pass ratio of default read operations of a memory device is an important parameter that determines the performance of the memory device. In some cases, default read operations of memory cells in a memory device can be performed by applying default read voltages to word lines coupled to the memory cells. When a memory cell in the memory device is at a beginning of life (BOL) phase, for example, when the memory device has been baked at 55 degrees Celsius for six hours, large even edge read margin and small odd edge read margin are needed to maintain high pass ratio. When the memory cell is at an end of life (EOL) phase, for example, when the memory device is at −25 degrees Celsius, small even edge read margin and large odd edge read margin are needed to maintain high pass ratio. Therefore it becomes challenging to maintain high pass ratio for both the BOL and the EOL phases.

In some cases, if the pass ratio of the default read operations is lower than a predetermined threshold, additional operations, for example, read retry operations, can be performed to increase the pass ratio. The additional operations can lead to increased time and cost for performing default read operations.

This specification relates to memory devices, systems, and methods for improving read operations of memory devices, for example, by increasing the pass ratio of default read operations and/or reducing the number of times read voltages are applied to a word line during a read operation of a memory cell coupled to the word line.

In some cases, to increase the pass ratio of default read operations and/or reduce the number of times read voltages are applied during a read operation of a memory cell, example techniques are described to use multiple-strobe sensing to determine a piece of data read from the memory cell while a single read voltage is applied to the word line, by adaptively adjusting effective read voltages for reading the piece of data from the memory cell. In some cases, the disclosed method can be used when a read voltage corresponding to a higher state of the memory cell is applied to the word line, for example, when a read voltage corresponding to the highest state of an xLC is applied to the word line.

Implementations of the present disclosure can provide one or more of the following technical effects. For example, the pass ratio of default read operations of a memory device can be increased even when some threshold voltage ranges of memory cells in the memory device are shifted up and some threshold voltage ranges of the memory cells are shifted down due to usage conditions of the memory device, therefore leading to improved performance of the read operations. Furthermore, the number of read voltages applied during read operations can be reduced when compared to existing techniques for default read operations, therefore reducing the time needed to perform read operations. Additionally, no hardware changes are needed to implement the disclosed methods.

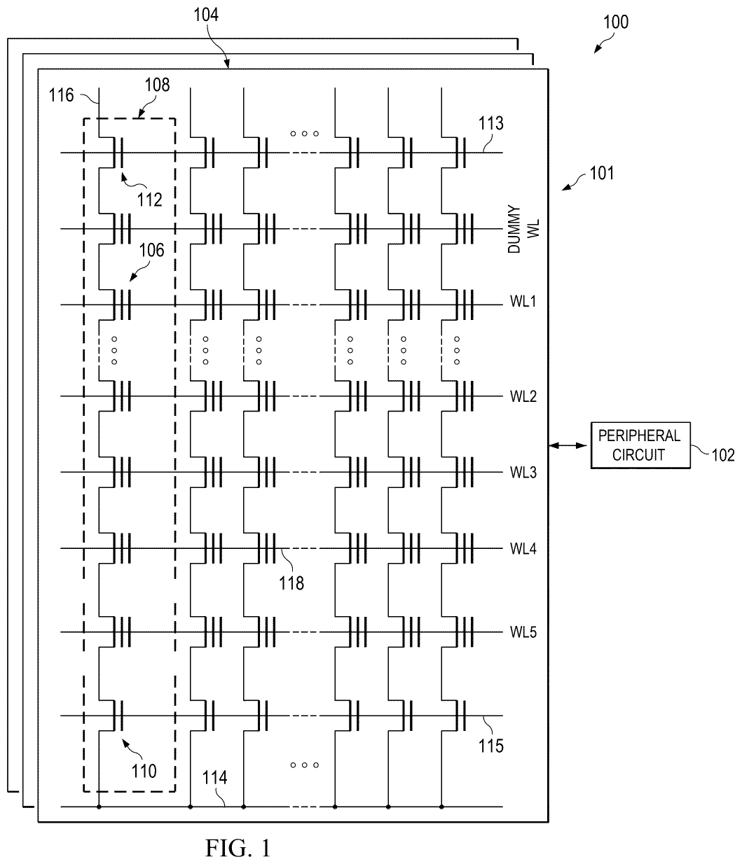

FIG. 1 illustrates an example of a schematic circuit diagram of a memory device 100 including peripheral circuits, according to some aspects of the present disclosure. Memory device 100 can include a memory cell array 101 and peripheral circuits 102 coupled to memory cell array 101. Memory cell array 101 can be a NAND Flash memory cell array in which memory cells 106 are provided in the form of an array of NAND memory strings 108 each extending vertically above a substrate (not shown). In some implementations, each NAND memory string 108 includes a plurality of memory cells 106 coupled in series and stacked vertically. Each memory cell 106 can hold a continuous, analog value, such as an electrical voltage or charge that depends on the number of electrons trapped within a region of memory cell 106. Each memory cell 106 can be either a floating gate type of memory cell including a floating-gate transistor or a charge trap type of memory cell including a charge-trap transistor.

In some implementations, each memory cell 106 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 106 is a multi-level cell (MLC) that is capable of storing more than a single bit of data in more than four memory states. For example, the MLC can store two bits per cell, three bits per cell (also known as triple-level cell (TLC)), or four bits per cell (also known as a quad-level cell (QLC)). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state.

As shown in FIG. 1 each NAND memory string 108 can include a source select gate (SSG) 110 at its source end and a drain select gate (DSG) 112 at its drain end. SSG 110 and DSG 112 can be configured to activate selected NAND memory strings 108 (columns of the array) during read and program operations. In some implementations, the sources of NAND memory strings 108 in the same block 104 are coupled through a same source line (SL) 114, e.g., a common SL. In other words, all NAND memory strings 108 in the same block 104 have an array common source (ACS), according to some implementations. DSG 112 of each NAND memory string 108 is coupled to a respective bit line 116 from which data can be read or written via an output bus (not shown), according to some implementations. In some implementations, each NAND memory string 108 is configured to be selected or deselected by applying a select voltage or a deselect voltage (e.g., 0 V) to respective DSG 112 through one or more DSG lines 113, and/or by applying a select voltage or a deselect voltage (e.g., 0 V) to respective SSG 110 through one or more SSG lines 115.

As shown in FIG. 1, NAND memory strings 108 can be organized into multiple blocks 104, each of which can have a common source line 114, e.g., coupled to the ACS. In some implementations, each block 104 is the basic data unit for erase operations, i.e., all memory cells 106 on the same block 104 are erased at the same time. To erase memory cells 106 in a selected block 104, source lines 114 coupled to selected block 104 as well as unselected blocks 104 in the same plane as selected block 104 can be biased with an erase voltage (Vers), such as a high positive voltage (e.g., 20 V or more). In some examples, erase operation may be performed at a half-block level, a quarter-block level, or a level having any suitable number of blocks or any suitable fractions of a block. Memory cells 106 of adjacent NAND memory strings can be coupled through word lines 118 that select which row of memory cells 106 is affected by read and program operations. Each word line 118 can include a plurality of control gates (gate electrodes) at each memory cell 106 and a gate line coupling the control gates. Example word lines (WLs) shown in FIG. 1 include dummy WL, WL1, WL2, WL3, WL4, and WL5 that are between one or more DSG lines 113 and one or more SSG lines 115.

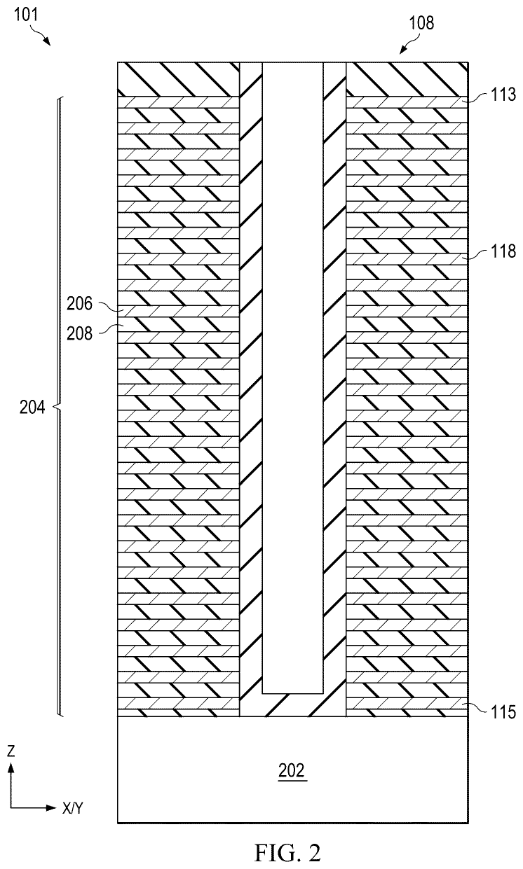

FIG. 2 illustrates an example of a side view of cross-sections of a memory cell array 101 including NAND memory strings 108, according to some aspects of the present disclosure. As shown in FIG. 2, NAND memory string 108 can extend vertically through a memory stack 204 above a substrate 202. Substrate 202 can include silicon (e.g., single crystalline silicon), silicon germanium (SiGe), gallium arsenide (GaAs), germanium (Ge), silicon on insulator (SOI), germanium on insulator (GOI), or any other suitable materials.

Memory stack 204 can include interleaved gate conductive layers 206 and gate-to-gate dielectric layers 208. The number of the pairs of gate conductive layers 206 and gate-to-gate dielectric layers 208 in memory stack 204 can determine the number of memory cells 106 in memory cell array 101. Gate conductive layer 206 can include conductive materials including, but not limited to, tungsten (W), cobalt (Co), copper (Cu), aluminum (Al), polysilicon, doped silicon, silicides, or any combination thereof. In some implementations, each gate conductive layer 206 includes a metal layer, such as a tungsten layer. In some implementations, each gate conductive layer 206 includes a doped polysilicon layer. Each gate conductive layer 206 can include control gates surrounding the memory cells 106, DSG 112, or SSG 110, and can extend laterally as DSG line 113 at the top of memory stack 204, SSG line 115 at the bottom of memory stack 204, or word line 118 between DSG line 113 and SSG line 115.

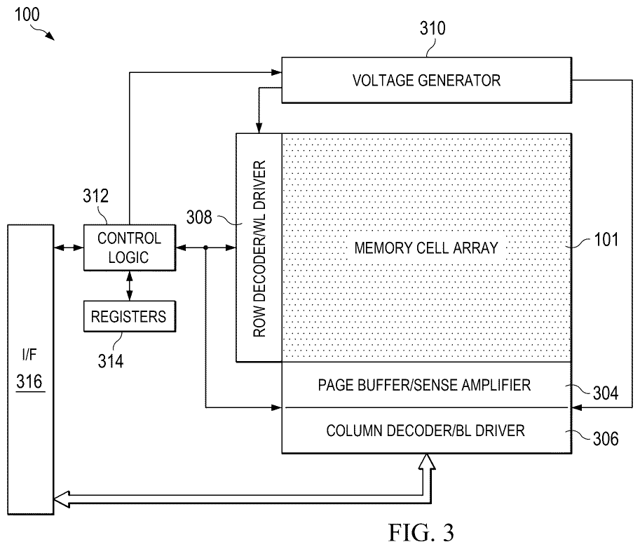

Peripheral circuits 102 can be coupled to memory cell array 101 through bit lines 116, word lines 118, source lines 114, SSG lines 115, and DSG lines 113. Peripheral circuits 102 can include any suitable analog, digital, and mixed-signal circuits for facilitating the operations of memory cell array 101 by applying and sensing voltage signals and/or current signals to and from each target memory cell of the memory cells 106 through bit lines 116, word lines 118, source lines 114, SSG lines 115, and DSG lines 113. Peripheral circuits 102 can include various types of peripheral circuits formed using metal-oxide-semiconductor (MOS) technologies. For example, FIG. 3 illustrates some example peripheral circuits, according to some aspects of the present disclosure. The example peripheral circuits include a page buffer/sense amplifier 304, a column decoder/bit line driver 306, a row decoder/word line driver 308, a voltage generator 310, control logic 312, registers 314, an interface 316, and a data bus. In some examples, additional peripheral circuits not shown in FIG. 3 may be included as well.

Page buffer/sense amplifier 304 can be configured to read and program (write) data from and to memory cell array 101 according to the control signals from control logic 312. In one example, page buffer/sense amplifier 304 may store one page of program data (write data) to be programmed into one page of memory cell array 101. In another example, page buffer/sense amplifier 304 may perform program verify operations to ensure that the data has been properly programmed into memory cells 106 coupled to selected word lines 118. In still another example, page buffer/sense amplifier 304 may also sense, for example, at sensing node (SO) 418, the low power signals from bit line 116 that represents a data bit stored in memory cell 106 and amplify the small voltage swing to recognizable logic levels in a read operation. Column decoder/bit line driver 306 can be configured to be controlled by control logic 312 and select one or more NAND memory strings 108 by applying bit line voltages generated from voltage generator 310.

Row decoder/word line driver 308 can be configured to be controlled by control logic 312 and select/deselect blocks 104 of memory cell array 101 and select/deselect word lines 118 of block 104. Row decoder/word line driver 308 can be further configured to drive word lines 118 using word line voltages generated from voltage generator 310. In some implementations, row decoder/word line driver 308 can also select/deselect and drive SSG lines 115 and DSG lines 113 as well. Row decoder/word line driver 308 can be configured to apply a read voltage to selected word line 118 in a read operation on memory cell 106 coupled to selected word line 118.

Voltage generator 310 can be configured to be controlled by control logic 312 and generate the word line voltages (e.g., read voltage, program voltage, pass voltage, local voltage, verification voltage, etc.), bit line voltages, and source line voltages to be supplied to memory cell array 101.

Control logic 312 can be coupled to each peripheral circuit described above and configured to control operations of each peripheral circuit. Registers 314 can be coupled to control logic 312 and include status registers, command registers, and address registers for storing status information, command operation codes (OP codes), and command addresses for controlling the operations of each peripheral circuit. The status registers of registers 314 can include one or more registers configured to store open block information indicative of the open block(s) of all blocks 104 in memory cell array 101, such as having an auto dynamic start voltage (ADSV) list. In some implementations, the open block information is also indicative of the last programmed page of each open block.

Interface 316 can be coupled to control logic 312 and act as a control buffer to buffer and relay control commands received from a host (not shown) to control logic 312 and status information received from control logic 312 to the host. Interface 316 can also be coupled to column decoder/bit line driver 306 via a data bus and act as a data input/output (I/O) interface and a data buffer to buffer and relay the data to and from memory cell array 101.

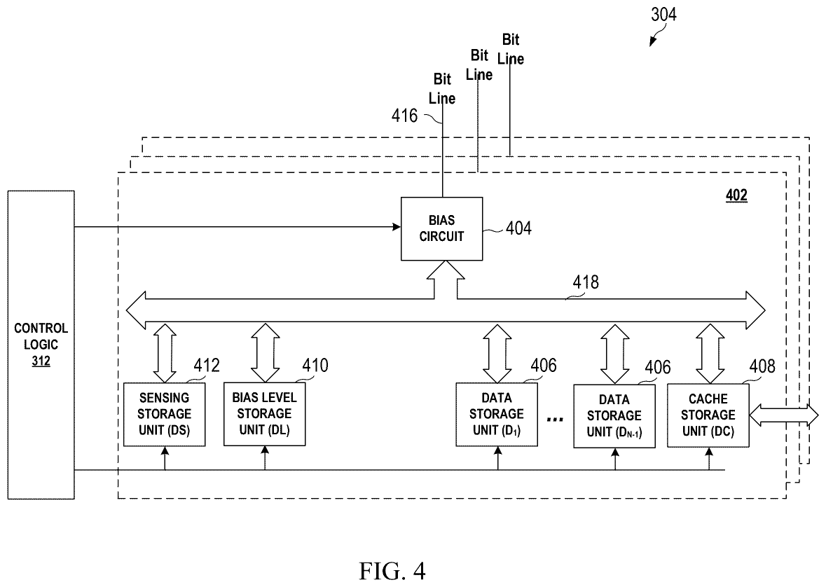

FIG. 4 illustrates a detailed block diagram of an example structure of a page buffer (e.g., page buffer/sense amplifier 304), according to some aspects of the present disclosure. In some implementations, the page buffer in FIG. 4 includes a plurality of page buffer circuits 402 each coupled to a respective one of bit lines 416. In other words, each page buffer circuit 402 can be coupled to a respective column of memory cells through a corresponding bit line 416 and configured to temporarily store a set of N-bits data that is used for programming a respective select memory cell in a program operation. All page buffer circuits 402 in the page buffer together can temporarily store the entire current data page (e.g., Q sets of the N-bits data) that are used for programming a select row of memory cells coupled to a select word line in the program operation. As described above, in some implementations, each page buffer circuit 402 is also configured to pre-process a respective portion of the user data received from data bus 218 and convert it to the corresponding set of N-bits data based on a preset gray code. The corresponding set of N-bits data may include N portions of page data (e.g., N bits from the current data page). For example, for TLCs where N=3, each page buffer circuit 402 may be configured to temporarily store a respective set of the 8 sets of 3 bits of the current data page, where the respective set corresponds to one of 8 levels.

In some implementations, each page buffer circuit 402 can include a plurality of non-dynamic storage units and a bias circuit 404. The plurality of non-dynamic storage units may include N−1 data storage units (D₁, . . . , D_{N-1}) 406, a cache storage unit (DC) 408, a bias level storage unit (DL) 410, and a sensing storage unit (DS) 412.

It is understood that each non-dynamic storage unit (such as data storage unit 406, cache storage unit 408, bias level storage unit 410, and sensing storage unit 412) may be any circuit that has two stable states for storing a single bit of data, such as a latch or a flip-flop. In some implementations, each of data storage unit 406, cache storage unit 408, bias level storage unit 410, and sensing storage unit 412 may include a latch. For example, page buffer circuit 402 may have a 4-latch configuration that includes one cache latch, one data latch, one 3-bias-level (3BL) latch, and one sensing latch for a TLC memory device. In another example, page buffer circuit 402 may have a 5-latch configuration that includes one cache latch, two data latches, one 3-bias-level latch, and one sensing latch for a QLC memory device.

During a current program operation for programming a select row of memory cells based on a current data page, each of N−1 data storage units 406 can be configured to store a respective portion of page data from the set of the N-bits data (e.g., a respective bit of the corresponding N bits from the current data page). As a result, N−1 data storage units 406 can store N−1 portions of page data from the set of the N-bits data (e.g., N−1 bits of the corresponding N bits from the current data page).

To reduce the number of non-dynamic storage units and the size of page buffer circuit 402, the number of cache storage unit 408 is limited to one, i.e., a single cache storage unit 408 that can store only a single bit of data at the same time, according to some implementations. In some cases, the number of data storage units in each page buffer circuit 402 can be at least the same as the number of bits in the set of N-bits data used for programming the corresponding select memory cell, i.e., N data storage units, because the single cache storage unit is dedicated to caching the data of the next data page. In some other cases, the single cache storage unit 408 in page buffer circuit 402 in FIG. 3 can also be configured to store one of the corresponding N bits from the current data page. That is, cache storage unit 408 is configured to sequentially store one of the corresponding N bits from the current data page and each of the corresponding N bits from the next data page, according to some implementations. In other words, cache storage unit 408 can act as both a data storage unit and a cache storage unit in a time-division manner to replace one of data storage units 406 in each page buffer circuit 402. Additionally, bias level storage unit 410 may be configured to store another one of the corresponding N bits from the current data page.

In some implementations, another storage unit in each page buffer circuit 402 for storing non-data page information is configured to sequentially store the non-data page information and one of the N bits of the next data page, thereby enabling the caching of all N−1 bits of the next data page in the current program operation to avoid the data loading windows. That is, page buffer circuit 402 can include a multipurpose storage unit that can store the non-data page information and cache the data of the next data page in a time-division manner. For example, sensing storage unit (DS) 412 or bias level storage unit (DL) 410 may be configured to store non-data page information, i.e., any information other than the data bits in a data page.

For example, sensing storage unit (DS) 412 may be configured to store information indicative of whether the current operation performed by page buffer/sense amplifier 304 is a read operation or a program operation. Bias level storage unit (DL) 410 (e.g., a 3-bias-level storage unit) may be configured to store the bias information of the respective bit line 416 coupled to page buffer circuit 402. In some implementations, bias level storage unit 410 may be a multipurpose storage unit that acts as both a bias level storage unit and a data storage unit in a time-division manner. Bias circuit 404 may be coupled to a respective bit line 416 and configured to apply a bit line voltage to corresponding select memory cell coupled to a respective bit line 416 in the program operation. Depending on whether the corresponding select memory cell passes the verification at the respective level according to the N bits of data for programming the select memory cell, for example, a high voltage level and a low voltage level, can be used as a bias level to determine a bit line voltage to be applied to the respective bit line 416 in a next program operation. In some implementations, to optimize the threshold voltage distributions, for example, enlarging the read margins between adjacent levels and reducing the width of each level, a medium voltage level is also used as the bias level to determine the bit line voltage in the next program operation. That is, one of three voltage levels, e.g., high, medium, and low (referred to herein as 3-bias-level), can be used as the bias level to determine the bit line voltage applied to the respective bit line 416 in the next program operation. In some implementations, the bias level is non-data page information stored in bias level storage unit 410.

It is understood that although bias level storage unit 410 is described herein as an example of the multipurpose storage unit, any suitable non-data page storage units in page buffer circuit 402, such as sensing storage unit 412, or any other non-data page storage units not shown in FIG. 4, may be used as the multipurpose storage unit in some examples without adding additional storage units into page buffer circuit 402.

In some implementations, control logic 312 may be configured to determine a type of an operation to be performed on page buffer circuit 402.

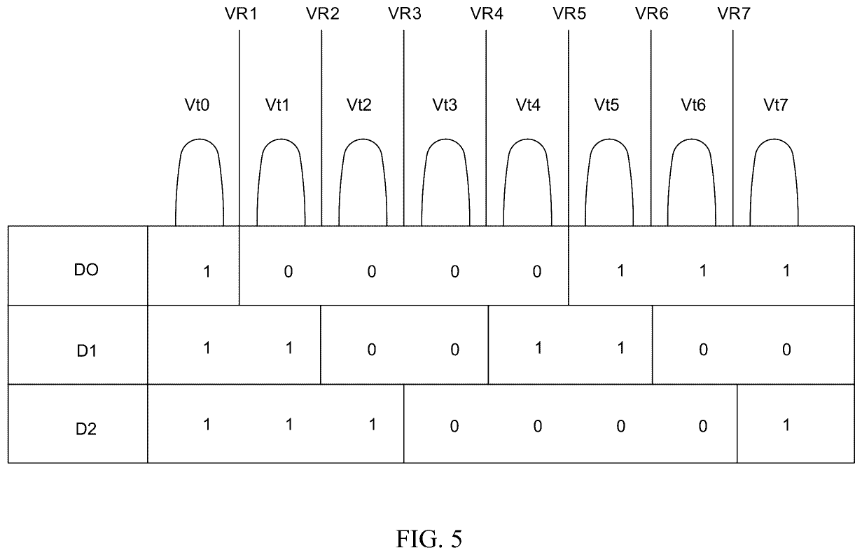

FIG. 5 illustrates example threshold voltage distributions of a TLC, according to some aspects of the present disclosure. In some implementations, each memory cell 106 can be configured to store a piece of N-bits data in one of 2^{N} levels (i.e., states), where N is an integer greater than 1 (e.g., N=2 for MLCs, N=3 for TLCs, and N=4 for QLCs). Each level can correspond to one of 2^{N} threshold voltage ranges of memory cells 106. When N=3, memory cell 106 is a TLC and has eight threshold voltage (Vt) ranges, for example, Vt0 to Vt7 in FIG. 5, representing three bits of data (D0, D1, D2), (also referred to as lower page (LP) data, middle page (MP) data, and upper page (UP) data respectively). During a programming operation, memory cell 106 is programmed to one of the Vt ranges according to the three-bit data to be programmed. During a read operation, memory cell 106's Vt range is checked and then converted to a three-bit data.

In some implementations, the three-bit data can be read independently. The seven thick vertical bars in FIG. 5 indicate the read voltages used to read each bit. For example, to read the D0 bit, the word line coupled to memory cell 106 is sequentially supplied with read voltages VR1 and VR5. To read the D1 bit, the word line is sequentially supplied with read voltages VR2, VR4, and VR6. To read the D2 bit, the word line is sequentially supplied with read voltages VR3 and VR7.

In some implementations, for each word line voltage, memory cell 106's data can be read by a page buffer circuit (e.g., at SO 418 in page buffer circuit 402). The page buffer circuit can generate an output of data 1 or data 0. The data read by each word line voltage can be stored in a data latch inside a page buffer. Then, the control logic coupled to memory cell 106 can generate the D0, D1, or D2 bit data according to the data stored in the data latches.

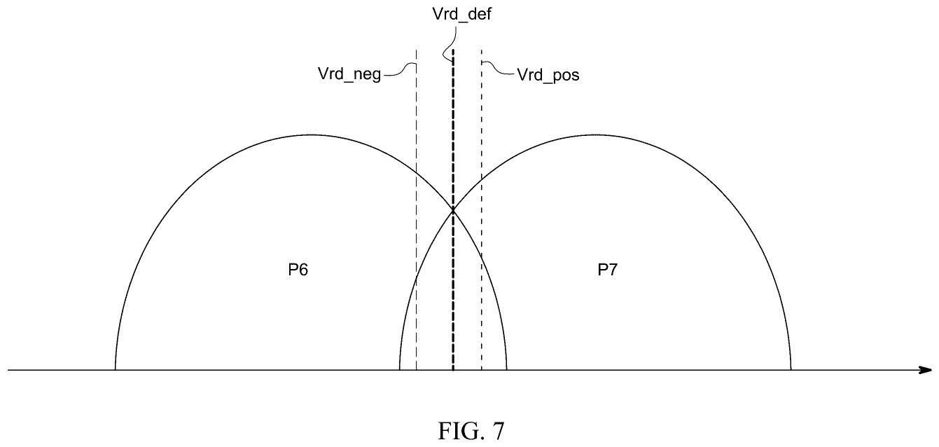

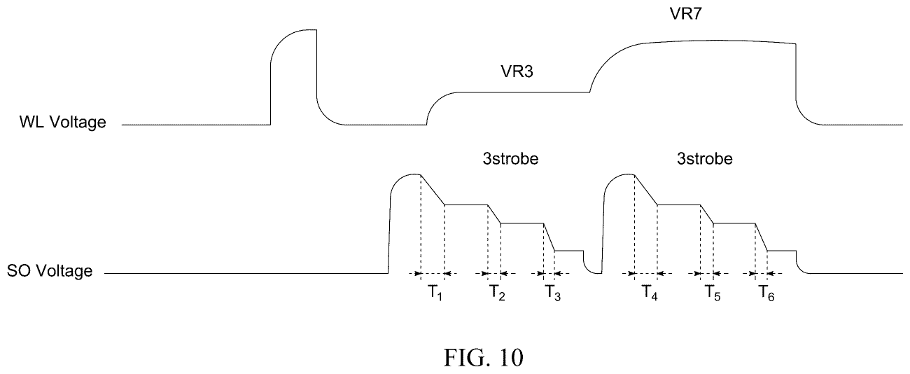

In some implementations, multiple-strobe sensing operations (e.g., three-strobe sensing operations) can be used to sense the data stored in memory cell 106. For example, during a three-strobe sensing operation, a read voltage (e.g., VR7 in FIG. 5) can be applied to the word line coupled to memory cell 106 to read a one-bit data from memory cell 106 (e.g., 0 or 1), such that SO 418 is discharging during the three-strobe sensing operation, and three voltages can be sensed at SO 418 at three time instances (e.g., three time instances in time durations T4, T5, and T6 in FIG. 10) respectively, when SO 418 is discharging. The three voltages can respectively correspond to three pieces of output data read from memory cell 106 during the three-strobe sensing operation. A final output data corresponding to the one-bit data from memory cell 106 can be determined from the three pieces of output data read during the three-strobe sensing operation. Additional details of the three-strobe sensing operation will be described in FIGS. 7-12 later.

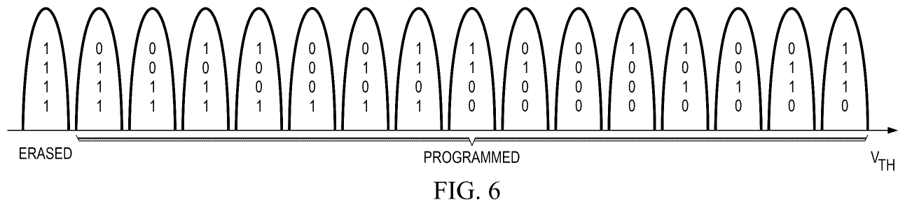

FIG. 6 illustrates example threshold voltage distributions of a QLC, according to some aspects of the present disclosure. In some implementations, memory cell 106 may be programmed into one of 16 levels, including one level of an erased state and 15 levels of programmed states. Each level may correspond to a respective threshold voltage range of memory cells 106. For example, the level corresponding to the lowest threshold voltage range (the left-most threshold voltage distribution in FIG. 6) may be considered as level 0, the level corresponding to the second-lowest threshold voltage range (the second left-most threshold voltage distribution in FIG. 6) may be considered as level 1, and so on until level 15 corresponding to the highest threshold voltage range (the right-most threshold voltage distribution in FIG. 6).

In some implementations, each of the 16 levels can correspond to one of the 16 pieces of N-bits data that is to be stored in target memory cell 106. In some cases, the 16 pieces of 4-bits data may be represented, for example, by (in the form of) a gray code. A gray code (a.k.a., reflected binary code (RBC) or reflected binary (RB)) is an ordering of the binary numeral system such that two successive values differ in only one bit (binary digit). For example, Table 1 below shows an example of a binary code representing a one-to-one mapping between 16 levels (level 0 to level 15) and 16 pieces of 4-bit data used in the example of FIG. 6. As shown in Table 1, each piece of 4-bits data may consist of four bits of binary values (b1, b2, b3, and b4). In one example, level 1 may correspond to a piece of 4-bits data having a value of 1111. In another example, level 15 may correspond to another piece of 4-bits data having a value of 1110.

TABLE 1

| Level | 0 | 1 | 2 | 3 | 4 | 5 | 6 | 7 | 8 | 9 | 10 | 11 | 12 | 13 | 14 | 15 |
|---|---|---|---|---|---|---|---|---|---|---|---|---|---|---|---|---|
| b1 | 1 | 0 | 0 | 0 | 1 | 1 | 0 | 0 | 0 | 0 | 0 | 1 | 1 | 1 | 1 | 1 |
| b2 | 1 | 1 | 1 | 0 | 0 | 0 | 0 | 1 | 1 | 0 | 0 | 0 | 0 | 1 | 1 | 1 |
| b3 | 1 | 1 | 1 | 1 | 1 | 0 | 0 | 0 | 0 | 0 | 1 | 1 | 0 | 0 | 0 | 1 |
| b4 | 1 | 1 | 0 | 0 | 0 | 0 | 0 | 0 | 1 | 1 | 1 | 1 | 1 | 1 | 0 | 0 |

FIG. 7 illustrates an example of using effective read voltages during a read operation of a memory cell in a memory cell array, according to some aspects of the present disclosure. In some implementation, the read operation can be a default read operation. During the read operation, when a read voltage (i.e., first voltage, such as VR7 in FIG. 5) is applied to a word line coupled to the memory cell to read a piece of one-bit data (i.e., first piece of data, such as data 1 or data 0) from the memory cell, a multiple-strobe sensing operation (e.g., a three-strobe sensing operation) can be performed at the sensing node (e.g., SO 418) of a page buffer circuit (e.g., page buffer circuit 402) coupled to the memory cell, to sense multiple voltages (e.g., first, second, and third sensed voltages) at the sensing node at multiple time instances (e.g., first, second, and third time instances), for example, at three time instances in time durations T4, T5, and T6 in FIG. 10 respectively. Each of the sensed voltages can be equivalent to a voltage sensed at the sensing node when an effective read voltage (i.e., one of a plurality of effective read voltages), such as Vrd_pos, Vrd_def, or Vrd_neg in FIG. 7, is applied to the word line coupled to the memory cell to read the data in the memory cell, even though only one read voltage (i.e., first voltage, such as VR7 in FIG. 5) is applied to the word line coupled to the memory cell during the read operation when the multiple voltages at the sensing node are sensed at the multiple time instances. Each of the effective read voltages can correspond to a piece of data (i.e., one of a plurality of pieces of estimated data) read from the memory cell at the corresponding time instance.

In some implementations, one of the effective read voltages can have the same value as the read voltage (i.e., first voltage, such as VR7 in FIG. 5) applied to the word line. For example, during a three-strobe sensing operation when VR7 in FIG. 10 is applied to the word line, effective read voltage Vrd_def corresponding to a sensing time instance in time duration T5 in FIG. 10 can have the same value as the read voltage VR7 applied to the word line. Vrd_pos corresponding to a sensing time instance in time duration T4 in FIG. 10 can be higher than Vrd_def, and Vrd_neg corresponding to a sensing time instance in time duration T6 in FIG. 10 can be lower than Vrd_def.

In some implementations, after the respective piece of data corresponding to each of the effective read voltages is read during a multiple-strobe sensing operation, the piece of one-bit data (i.e., first piece of data) of the memory cell corresponding to the read voltage applied to the word line can be selected from the pieces of data corresponding to the effective read voltages. For example, during a three-strobe sensing operation when VR7 in FIG. 10 is applied as a read voltage to the word line, a total number of memory cells in the memory cell array (i.e., first memory cells) that have threshold voltages higher than the read voltage applied to the word line (i.e., first voltage) can be counted, for example, by a verify failbit count (VFC) operation. Then the total number of first memory cells can be compared to two preset thresholds (i.e., first threshold and second threshold), with the second threshold higher than the first threshold.

In some implementations, when the total number of the first memory cells is larger than the second threshold, the piece of data corresponding to the highest effective read voltage (i.e., third effective read voltage, such as Vrd_pos in FIG. 7) can be selected as the piece of one-bit data corresponding to the read voltage applied to the word line. When the total number of the first memory cells is smaller than the first threshold, the piece of data corresponding to the lowest effective read voltage (i.e., second effective read voltage, such as Vrd_neg in FIG. 7) can be selected as the piece of one-bit data corresponding to the read voltage applied to the word line. When the total number of the first memory cells is larger than or equal to the first threshold and smaller than or equal to the second threshold, the piece of data corresponding to the effective read voltage that equals the read voltage applied to the word line (i.e., first effective read voltage, such as Vrd_def in FIG. 7) can be selected as the piece of one-bit data corresponding to the read voltage applied to the word line. The determination of the two thresholds is described next.

In some implementations, the two preset thresholds depend on the read voltage applied to the word line. For example, during a read operation of a TLC, when VR7 in FIG. 5 is applied as the read voltage to the word line, one-eighth of all memory cells in the memory cell array have threshold voltages above VR7, if the eight threshold voltage ranges Vt0 to Vt7 in FIG. 5 are uniformly distributed among all memory cells in the memory cell array. Therefore, the second threshold can be a number larger than one-eighth of the total number of all memory cells in the memory cell array, for example, twenty more than one-eighth of the total number of all memory cells in the memory cell array, such that when the total number of the first memory cells is larger than the second threshold, it can be determined that more than one-eighth of all memory cells in the memory cell array have threshold voltages higher than VR7 in FIG. 5, and consequently the piece of data corresponding to the highest effective read voltage (e.g., Vrd_pos in FIG. 7) can be selected as the piece of one-bit data corresponding to the read voltage applied to the word line. Similarly, the first threshold can be a number smaller than one-eighth of the total number of all memory cells in the memory cell array, for example, twenty less than one-eighth of the total number of memory cells in the memory cell array, such that when the total number of the first memory cells is smaller than the first threshold, it can be determined that less than one-eighth of all memory cells in the memory cell array have threshold voltages higher than VR7 in FIG. 5, and consequently the piece of data corresponding to the lowest effective read voltage (e.g., Vrd_neg in FIG. 7) can be selected as the piece of one-bit data corresponding to the read voltage applied to the word line. In some cases, the method described above for determining the first threshold and the second threshold can be similarly used when other read voltages (e.g., VR1 to VR6 in FIG. 5) are applied to the word line during the read operation of the TLC, with the portion of the total number of all memory cells (e.g., one-eighth) in the first and the second thresholds adjusted according to the read voltage applied to the word line. The method described above can also be applied to read operations of other xLCs (e.g., MLCs or QLCs).

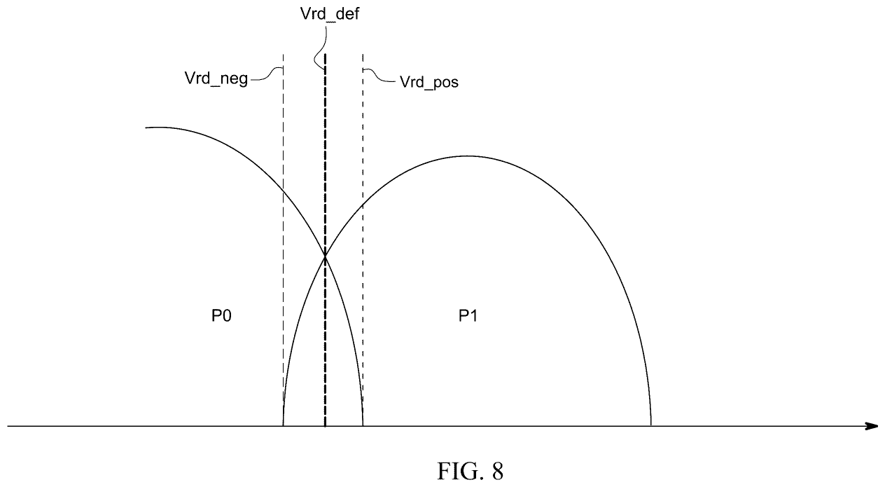

FIG. 8 illustrates a second example of using effective read voltages during a read operation of a memory cell in a memory cell array, according to some aspects of the present disclosure. In some implementations, the method described in the example of FIG. 7 for obtaining the piece of one-bit data from the memory cell can also be used in the example of FIG. 8, with the differences described below.

In some implementations, the difference between the two examples in FIG. 7 and FIG. 8 is that in FIG. 7, VR7 in FIG. 5 is applied as a read voltage to a word line coupled to the memory cell to read a piece of one-bit data from the memory cell, whereas in FIG. 8, VR1 in FIG. 5 is applied as a read voltage to the word line to read a piece of one-bit data from the memory cell. Consequently, the differences between the two examples in FIG. 7 and FIG. 8 in obtaining the piece of one-bit data from the memory cell are (1) in the determination of the first memory cells and (2) in the determination of the two preset thresholds (i.e., first threshold and second threshold).

For example, in FIG. 7, the first memory cells are determined to be the memory cells in the memory cell array that have threshold voltages higher than the read voltage applied to the word line (i.e., first voltage), whereas in FIG. 8, the first memory cells are determined to be the memory cells in the memory cell array that have threshold voltages higher than the highest effective read voltage (e.g., Vrd_pos in FIG. 8).

As another example, in FIG. 7, because VR7 in FIG. 5 is applied as a read voltage to the word line, the first threshold is determined to be smaller than one-eighth of the total number of memory cells in the memory cell array, and the second threshold is determined to be larger than one-eighth of the total number of memory cells in the memory cell array. In contrast, in FIG. 8, because VR1 in FIG. 5 is applied as a read voltage to the word line, the first threshold is determined to be smaller than seven-eighth of the total number of memory cells in the memory cell array, and the second threshold is determined to be larger than seven-eighth of the total number of memory cells in the memory cell array.

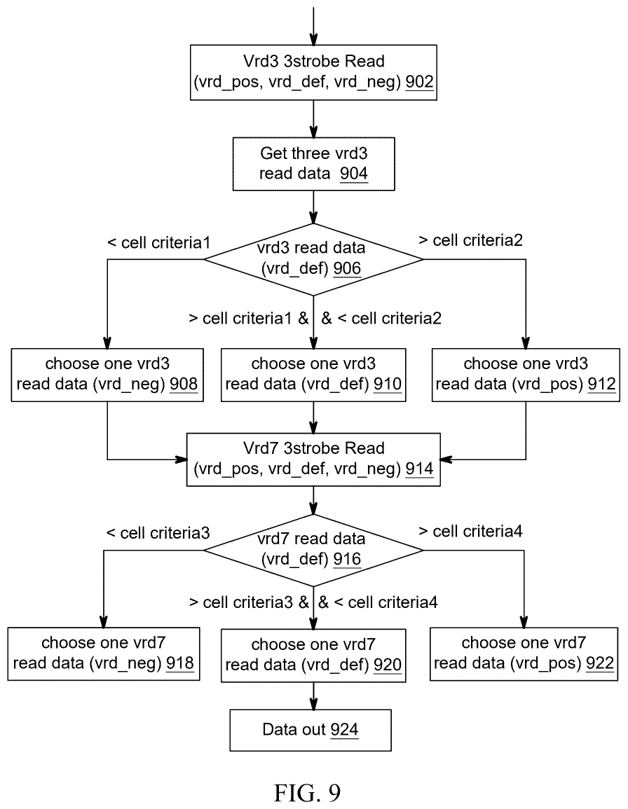

FIG. 9 illustrates an example workflow of performing a read operation of a memory cell in a memory cell array, according to some aspects of the present disclosure. In some implementations, the memory cell is a TLC with eight threshold voltage ranges Vt0 to Vt7 shown in FIG. 5, and the read voltages VR3 and VR7 in FIG. 5 are applied sequentially to a word line coupled to the memory cell to read D2 bit data (also referred to as upper page data) in FIG. 5.

At 902, when VR3 in FIG. 5 is applied to the word line, a three-strobe sensing operation is performed at a sensing node, for example, at SO 418 in FIG. 4, to obtain three pieces of data read from the memory cell that correspond to three effective read voltages (e.g., Vrd_pos, Vrd_def, and Vrd_neg) applied to the word line coupled to the memory cell, based on three voltages sensed at the sensing node at three time instances, for example, during the time durations T1, T2, and T3 in FIG. 10 respectively. In some implementations, the three effective read voltages can be equivalent to three voltages applied to the word line (e.g., word line 118 in FIG. 1) coupled to the memory cell and used to read the three pieces of data from the memory cell. Vrd_def can have the same value as the read voltage VR3 applied to the word line. Vrd_pos can be higher than Vrd_def, and Vrd_neg can be lower than Vrd_def. The three effective read voltages can respectively correspond to the three pieces of data read from the memory cell during the three-strobe sensing operation (e.g., three pieces of Vrd3 read data in FIG. 9).

At 904, the three pieces of data read from the memory cell are obtained.

At 906, a total number of memory cells in the memory cell array (i.e., first memory cells) that have threshold voltages higher than VR3 can be counted, for example, by a verify failbit count operation. Then the total number of first memory cells can be compared to two preset thresholds (i.e., first threshold and second threshold, such as cell criteria1 and cell criteria2 in FIG. 9), with the second threshold higher than the first threshold.

At 908, when the total number of the first memory cells is smaller than the first threshold (e.g., cell criteria1 in FIG. 9), the piece of data corresponding to the lowest effective read voltage (i.e., second effective read voltage, such as Vrd_neg) can be selected as the piece of one-bit data corresponding to the read voltage applied to the word line.

At 910, when the total number of the first memory cells is larger than the first threshold (e.g., cell criteria1 in FIG. 9) and smaller than the second threshold (e.g., cell criteria2 in FIG. 9), the piece of data corresponding to the effective read voltage that equals VR3 (e.g., Vrd_pos) can be selected as the piece of one-bit data corresponding to the read voltage applied to the word line.

At 912, when the total number of the first memory cells is larger than the second threshold (e.g., cell criteria2 in FIG. 9), the piece of data corresponding to the highest effective read voltage (i.e., third effective read voltage, such as Vrd_pos) can be selected as the piece of one-bit data corresponding to the read voltage applied to the word line.

In some implementations, the two preset thresholds (e.g., cell criteria1 and cell criteria2 in FIG. 9) depend on the read voltage applied to the word line. For example, when VR3 in FIG. 5 is applied as the read voltage to the word line, five-eighth of all memory cells in the memory cell array have threshold voltages above VR3, if the eight threshold voltage ranges Vt0 to Vt7 in FIG. 5 are uniformly distributed among all memory cells in the memory cell array. Therefore, the second threshold can be a number larger than five-eighth of the total number of all memory cells in the memory cell array, for example, twenty more than five-eighth of the total number of all memory cells in the memory cell array, such that when the total number of the first memory cells is larger than the second threshold, it can be determined that more than five-eighth of all memory cells in the memory cell array have threshold voltages higher than VR3 in FIG. 5, and consequently the piece of data corresponding to the highest effective read voltage (e.g., Vrd_pos) can be selected as the piece of one-bit data corresponding to the read voltage VR3 applied to the word line. Similarly, the first threshold can be a number smaller than five-eighth of the total number of all memory cells in the memory cell array, for example, twenty less than five-eighth of the total number of memory cells in the memory cell array, such that when the total number of the first memory cells is smaller than the first threshold, it can be determined that less than five-eighth of all memory cells in the memory cell array have threshold voltages higher than VR3 in FIG. 5, and consequently the piece of data corresponding to the lowest effective read voltage (e.g., Vrd_neg) can be selected as the piece of one-bit data corresponding to the read voltage VR3 applied to the word line.

In some implementations, after the piece of one-bit data corresponding to read voltage VR3 applied to the word line is determined at one of 902 to 912 in FIG. 9, the piece of one-bit data corresponding to read voltage VR3 applied to the word line can be determined next at 914 to 922 in FIG. 9.

At 914, when VR7 in FIG. 5 is applied to the word line, a three-strobe sensing operation is performed, for example, at SO 418 in FIG. 3, to obtain three pieces of data read from the memory cell that correspond to three effective read voltages (e.g., Vrd_pos, Vrd_def, and Vrd_neg) applied to the word line coupled to the memory cell, based on three voltages sensed at the sensing node at three time instances, for example, during the time durations T4, T5, and T6 in FIG. 10 respectively. In some implementations, the three effective read voltages can be equivalent to three voltages applied to the word line (e.g., word line 118 in FIG. 1) coupled to the memory cell and used to read the three pieces of data from the memory cell. Vrd_def can have the same value as the read voltage VR7 applied to the word line. Vrd_pos can be higher than Vrd_def, and Vrd_neg can be lower than Vrd_def. The three effective read voltages can respectively correspond to three pieces of data read from the memory cell during the three-strobe sensing operation (e.g., three pieces of Vrd7 read data in FIG. 9).

At 916, a total number of memory cells in the memory cell array (i.e., first memory cells) that have threshold voltages higher than VR7 can be counted, for example, by a verify failbit count operation. Then the total number of first memory cells can be compared to two preset thresholds (i.e., first threshold and second threshold, such as cell criteria3 and cell criteria4 in FIG. 9), with the second threshold higher than the first threshold.

At 918, when the total number of the first memory cells is smaller than the first threshold (e.g., cell criteria3 in FIG. 9), the piece of data corresponding to the lowest effective read voltage (i.e., second effective read voltage, such as Vrd_neg) can be selected as the piece of one-bit data corresponding to the read voltage applied to the word line.

At 920, when the total number of the first memory cells is larger than the first threshold (e.g., cell criteria3 in FIG. 9) and smaller than the second threshold (e.g., cell criteria4 in FIG. 9), the piece of data corresponding to the effective read voltage that equals VR3 (e.g., Vrd_pos) can be selected as the piece of one-bit data corresponding to the read voltage applied to the word line.

At 922, when the total number of the first memory cells is larger than the second threshold (e.g., cell criteria4 in FIG. 9), the piece of data corresponding to the highest effective read voltage (i.e., third effective read voltage, such as Vrd_pos) can be selected as the piece of one-bit data corresponding to the read voltage applied to the word line.

In some implementations, the two preset thresholds (e.g., cell criteria3 and cell criteria4 in FIG. 9) depend on the read voltage applied to the word line. For example, when VR7 in FIG. 5 is applied as the read voltage to the word line, one-eighth of all memory cells in the memory cell array have threshold voltages above VR3, if the eight threshold voltage ranges Vt0 to Vt7 in FIG. 5 are uniformly distributed among all memory cells in the memory cell array. Therefore, the second threshold can be a number larger than one-eighth of the total number of all memory cells in the memory cell array, for example, twenty more than one-eighth of the total number of all memory cells in the memory cell array, such that when the total number of the first memory cells is larger than the second threshold, it can be determined that more than one-eighth of all memory cells in the memory cell array have threshold voltages higher than VR7 in FIG. 5, and consequently the piece of data corresponding to the highest effective read voltage (e.g., Vrd_pos) can be selected as the piece of one-bit data corresponding to the read voltage VR7 applied to the word line. Similarly, the first threshold can be a number smaller than one-eighth of the total number of all memory cells in the memory cell array, for example, twenty less than one-eighth of the total number of memory cells in the memory cell array, such that when the total number of the first memory cells is smaller than the first threshold, it can be determined that less than one-eighth of all memory cells in the memory cell array have threshold voltages higher than VR7 in FIG. 5, and consequently the piece of data corresponding to the lowest effective read voltage (e.g., Vrd_neg) can be selected as the piece of one-bit data corresponding to the read voltage VR7 applied to the word line.

At 924, after both the piece of one-bit data corresponding to read voltage VR3 applied to the word line and the piece of one-bit data corresponding to read voltage VR7 applied to the word line are determined, the upper page data of the memory cell (e.g., D2 bit data in FIG. 5) can be determined, for example, by performing an exclusive OR operation of the piece of one-bit data corresponding to read voltage VR3 applied to the word line and the piece of one-bit data corresponding to read voltage VR7 applied to the word line.

FIG. 10 illustrates example word line voltage and sensing node (SO) voltage during a read operation of a memory cell in a memory cell array, according to some aspects of the present disclosure. In some implementations, read voltages VR3 and VR7 in FIG. 10 are applied sequentially to a word line coupled to the memory cell to read D2 bit data (also referred to as upper page data) in FIG. 5.

In some implementations, when VR3 or VR7 is applied to the word line, a three-strobe sensing operation can be performed in a page buffer circuit (e.g., at SO 418 in page buffer circuit 402 in FIG. 3) while SO 418 is discharging, to obtain three pieces of data read from the memory cell that correspond to three effective read voltages (e.g., Vrd_pos, Vrd_def, and Vrd_neg in FIG. 7) applied to the word line coupled to the memory cell, based on three voltages sensed at the sensing node at three time instances, for example, during T1, T2, and T3 respectively when VR3 is applied to the word line, or during T4, T5, and T6 respectively when VR7 is applied to the word line.

In some implementations, one of the effective read voltages can have the same value as the read voltage applied to the word line. For example, during a three-strobe sensing operation when VR7 in FIG. 10 is applied to the word line, Vrd_def in FIG. 7, corresponding to a sensing time instance in time duration T5 in FIG. 10, can have the same value as the read voltage VR7 applied to the word line. Vrd_pos in FIG. 7, corresponding to a sensing time instance in time duration T4 in FIG. 10, can be higher than Vrd_def, and Vrd_neg in FIG. 7, corresponding to a sensing time instance in time duration T6 in FIG. 10, can be lower than Vrd_def.

In some implementations, the three effective read voltages can respectively correspond to three pieces of output data read from the memory cell during the three-strobe sensing operation. A final one-bit output data corresponding to the read voltage applied to the word line (e.g., VR3 or VR7 in FIG. 10) can be determined from the three pieces of output data read during the three-strobe sensing operation, for example, using the methods described for the examples in FIGS. 7, 8, and 12.

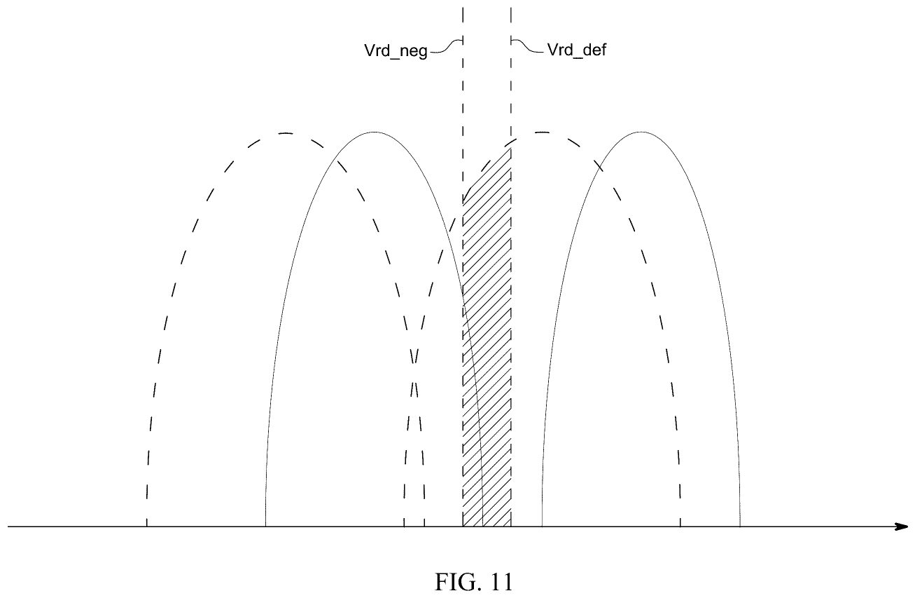

FIG. 11 illustrates a third example of using effective read voltages during a read operation of a memory cell in a memory cell array, according to some aspects of the present disclosure. In some implementation, the read operation can be a default read operation. During the read operation, when a read voltage (i.e., first voltage, such as VR7 in FIG. 5) is applied to a word line coupled to the memory cell to read a piece of one-bit data (i.e., first piece of data, such as data 1 or data 0) from the memory cell, a multiple-strobe sensing operation (e.g., a dual-strobe sensing operation) can be performed at the sensing node (e.g., SO 418) of a page buffer circuit (e.g., page buffer circuit 402) coupled to the memory cell, to obtain two pieces of data read from the memory cell that correspond to two effective read voltages (e.g., Vrd_def and Vrd_neg in FIG. 11) applied to the word line coupled to the memory cell, based on two voltages sensed at the sensing node at two time instances. Each of the effective read voltages can correspond to a piece of data (i.e., one of a plurality of pieces of estimated data) read from the memory cell at the corresponding time instance.

In some implementations, one of the effective read voltages can have the same value as the read voltage applied to the word line. For example, during a dual-strobe sensing operation when VR7 in FIG. 5 is applied to the word line, Vrd_def in FIG. 11 can have the same value as the read voltage VR7 applied to the word line, and Vrd_neg in FIG. 11 can be lower than Vrd_def.

In some implementations, after the respective piece of data corresponding to each of the effective read voltages is read during a multiple-strobe sensing operation, the piece of one-bit data (i.e., first piece of data) of the memory cell corresponding to the read voltage applied to the word line can be selected from the pieces of data corresponding to the effective read voltages. For example, during a dual-strobe sensing operation when VR7 in FIG. 5 is applied as a read voltage to the word line, a total number of memory cells in the memory cell array (i.e., first memory cells) that have threshold voltages between the lower effective read voltage (i.e., first effective read voltage, such as Vrd_neg in FIG. 11) and the effective read voltage that equals the read voltage applied to the word line (e.g., Vrd_def in FIG. 11) can be counted, for example, by a verify failbit count operation. Then the total number of first memory cells can be compared to a preset threshold (i.e., fourth threshold).

In some implementations, when the total number of the first memory cells is larger than the fourth threshold, the piece of data corresponding to the lower effective read voltage (e.g., Vrd_neg in FIG. 11) can be selected as the piece of one-bit data corresponding to the read voltage applied to the word line. When the total number of the first memory cells is smaller than the fourth threshold, the piece of data corresponding to the effective read voltage that equals the read voltage applied to the word line (e.g., Vrd_def in FIG. 11) can be selected as the piece of one-bit data corresponding to the read voltage applied to the word line. In some cases, the fourth threshold can be determined through testing of memory cell arrays under different conditions for read operations, for example, different BOL or EOL conditions for default read operations.

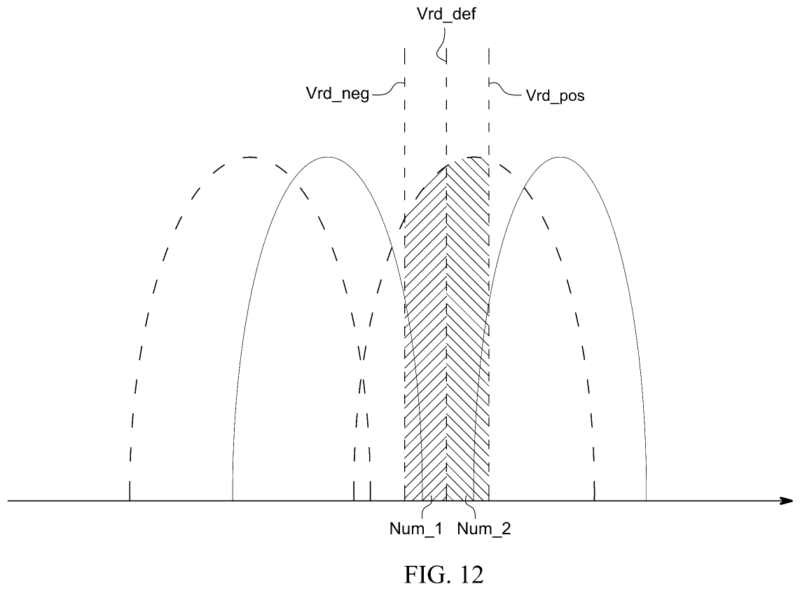

FIG. 12 illustrates a fourth example of using effective read voltages during a read operation of a memory cell in a memory cell array, according to some aspects of the present disclosure. In some implementation, the read operation can be a default read operation. During the read operation, when a read voltage (i.e., first voltage, such as VR7 in FIG. 5) is applied to a word line coupled to the memory cell to read a piece of one-bit data (i.e., first piece of data, such as data 1 or data 0) from the memory cell, a multiple-strobe sensing operation (e.g., a three-strobe sensing operation) can be performed at the sensing node (e.g., SO 418) of a page buffer circuit (e.g., page buffer circuit 402) coupled to the memory cell, to obtain three pieces of data read from the memory cell that correspond to three effective read voltages (e.g., Vrd_pos, Vrd_def, and Vrd_neg in FIG. 12) applied to the word line coupled to the memory cell, based on three voltages sensed at the sensing node at three time instances (i.e., first, second, and third time instances), for example, at three time instances in time durations T4, T5, and T6 in FIG. 10 respectively. Each of the effective read voltages can correspond to a piece of data (i.e., one of a plurality of pieces of estimated data) read from the memory cell at the corresponding time instance.

In some implementations, one of the effective read voltages can have the same value as the read voltage applied to the word line. For example, during a three-strobe sensing operation when VR7 in FIG. 10 is applied to the word line, Vrd_def corresponding to a sensing time instance in time duration T5 in FIG. 10 can have the same value as the read voltage VR7 applied to the word line. Vrd_pos corresponding to a sensing time instance in time duration T4 in FIG. 10 can be higher than Vrd_def, and Vrd_neg corresponding to a sensing time instance in time duration T6 in FIG. 10 can be lower than Vrd_def.

In some implementations, after the respective piece of data corresponding to each of the effective read voltages is read during a multiple-strobe sensing operation, the piece of one-bit data (i.e., first piece of data) of the memory cell corresponding to the read voltage applied to the word line can be selected from the pieces of data corresponding to the effective read voltages. For example, during a three-strobe sensing operation when VR7 in FIG. 10 is applied as a read voltage to the word line, a total number of memory cells in the memory cell array (i.e., first memory cells) that have threshold voltages between the lowest effective read voltage (i.e., first effective read voltage, such as Vrd_neg in FIG. 12) and the effective read voltage that equals the read voltage applied to the word line (e.g., Vrd_def in FIG. 12) can be counted, for example, by a verify failbit count operation and/or as Num_1 in FIG. 12. Then the total number of first memory cells can be compared to a preset threshold (i.e., third threshold). In some cases, the third threshold is equal to a total number of memory cells in the memory cell array that have threshold voltages between the effective read voltage that equals the read voltage applied to the word line (e.g., Vrd_def in FIG. 12) and the highest effective read voltage (i.e., second effective read voltage, such as Vrd_pos in FIG. 12). The third threshold can be counted by a verify failbit count operation and/or as Num_2 in FIG. 12.

In some implementations, when the total number of the first memory cells is larger than the third threshold, the piece of data corresponding to the highest effective read voltage (e.g., Vrd_pos in FIG. 12) can be selected as the piece of one-bit data corresponding to the read voltage applied to the word line. When the total number of the first memory cells is smaller than the third threshold, the piece of data corresponding to the lowest effective read voltage (e.g., Vrd_neg in FIG. 12) can be selected as the piece of one-bit data corresponding to the read voltage applied to the word line. When the total number of the first memory cells is equal to the third threshold, the piece of data corresponding to the effective read voltage that equals the read voltage applied to the word line (e.g., Vrd_def in FIG. 12) can be selected as the piece of one-bit data corresponding to the read voltage applied to the word line.

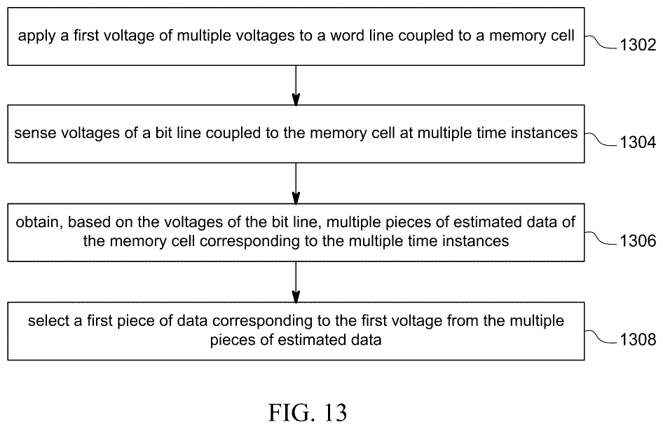

FIG. 13 is a flow chart of an example process 1300 for improving pass ratio in default read operations in a memory device, according to some aspects of the present disclosure. Process 1300 can be performed by any suitable device or system as described herein, for example, according to the example techniques described with respect to FIGS. 7-12. For example, process 1300 can be performed by a memory device, such as memory device 100. The memory device can include a memory cell array, such as, memory cell array 101, and a peripheral circuit 102. The memory device can be a part of a memory system, such as memory system 1402. The operations shown in process 1300 may not be exhaustive and that other operations can be performed as well before, after, or in between any of the illustrated operations. Further, some of the operations may be performed simultaneously, or in a different order than shown in FIG. 13. In some implementations, some of the operations may be performed by one or more components of a device or a system, such as, a peripheral circuit of the memory device.

At 1302, a first voltage of multiple voltages is applied to a word line coupled to the memory cell.

At 1304, voltages of a bit line coupled to the memory cell are sensed at multiple time instances.

At 1306, multiple pieces of estimated data of the memory cell corresponding to the multiple time instances are obtained based on the voltages of the bit line.

At 1308, a first piece of data corresponding to the first voltage is selected from the multiple pieces of estimated data.

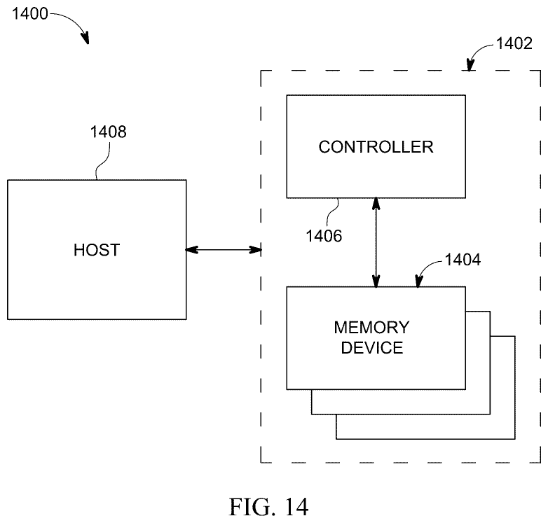

FIG. 14 illustrates a block diagram of an example system 1400 having a memory device, according to some aspects of the present disclosure. System 1400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 14, system 1400 can include a host 1408 and a memory system 1402 having one or more memory devices 1404 and a memory controller 1406. Host 1408 can be a processor of an electronic device, such as a central processing unit (CPU), or a system-on-chip (SoC), such as an application processor (AP). Host 1408 can be configured to send or receive data to or from memory devices 1404.

Memory device 1404 can be any memory device disclosed in the present disclosure. Memory controller 1406 is coupled to memory device 1404 and host 1408 and is configured to control memory device 1404, according to some implementations. Memory controller 1406 can manage the data stored in memory device 1404 and communicate with host 1408. In some implementations, memory controller 1406 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1406 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1406 can be configured to control operations of memory device 1404, such as read, erase, and program operations. Memory controller 1406 can also be configured to manage various functions with respect to the data stored or to be stored in memory device 1404 including, but not limited to bad-block management, garbage collection, logical-to-physical address conversion, wear leveling, etc. In some implementations, memory controller 1406 is further configured to process error correction codes (ECCs) with respect to the data read from or written to memory device 1404. Any other suitable functions may be performed by memory controller 1406 as well, for example, formatting memory device 1404.

Memory controller 1406 can communicate with an external device (e.g., host 1408) according to a particular communication protocol. For example, memory controller 1406 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

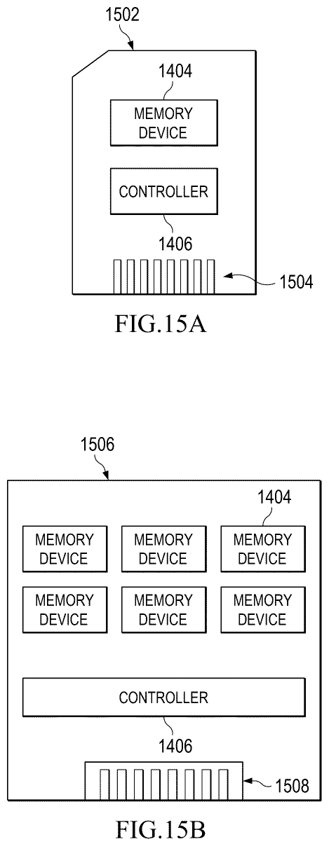

Memory controller 1406 and one or more memory devices 1404 can be integrated into various types of storage devices, for example, be included in the same package, such as a universal Flash storage (UFS) package or an eMMC package. That is, memory system 1402 can be implemented and packaged into different types of end electronic products. In one example shown in FIG. 15A, memory controller 1406 and a single memory device 1404 may be integrated into a memory card 1502. Memory card 1502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1502 can further include a memory card connector 1504 coupling memory card 1502 with a host (e.g., host 1408 in FIG. 14). In another example shown in FIG. 15B, memory controller 1406 and multiple memory devices 1404 may be integrated into an SSD 1506. SSD 1506 can further include an SSD connector 1508 coupling SSD 1506 with a host (e.g., host 1408 in FIG. 14). In some implementations, the storage capacity and/or the operation speed of SSD 1506 is greater than those of memory card 1502.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

As used in this disclosure, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, the phraseology or terminology employed in this disclosure, and not otherwise defined, is for the purpose of description only and not of limitation. Any use of section headings is intended to aid reading of the document and is not to be interpreted as limiting; information that is relevant to a section heading may occur within or outside of that particular section.

As used in this disclosure, the term “about” or “approximately” can allow for a degree of variability in a value or range, for example, within 10%, within 5%, or within 1% of a stated value or of a stated limit of a range.

As used in this disclosure, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

Particular implementations of the subject matter have been described. Other implementations, alterations, and permutations of the described implementations are within the scope of the following claims as will be apparent to those skilled in the art. While operations are depicted in the drawings or claims in a particular order, such operations are not required be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations are not required in all implementations, and the described components and systems can generally be integrated together or packaged into multiple products.

Accordingly, the previously described example implementations do not define or constrain the present disclosure. Other changes, substitutions, and alterations are also possible without departing from the spirit and scope of the present disclosure.

What is claimed is:

1. A memory device, comprising:
a memory cell array; and
a peripheral circuit coupled to the memory cell array and configured to perform operations comprising:
during a read operation of a memory cell in the memory cell array:
applying a first voltage of a plurality of voltages to a word line coupled to the memory cell;
sensing voltages of a bit line coupled to the memory cell at a plurality of time instances;
obtaining, based on the voltages of the bit line, a plurality of pieces of estimated data of the memory cell corresponding to the plurality of time instances; and
selecting a first piece of data corresponding to the first voltage from the plurality of pieces of estimated data.

2. The memory device according to claim 1, wherein selecting the first piece of data corresponding to the first voltage from the plurality of pieces of estimated data comprises:
determining a total number of first memory cells in the memory cell array; and
selecting, based on a comparison of the total number of first memory cells to one or more thresholds, the first piece of data corresponding to the first voltage from the plurality of pieces of estimated data.

3. The memory device according to claim 2, wherein a threshold voltage of each of the first memory cells is larger than a first effective read voltage of a plurality of effective read voltages of the memory cell, and wherein the plurality of pieces of estimated data correspond to the plurality of effective read voltages of the memory cell.

4. The memory device according to claim 3, wherein the memory cell is a triple-level cell (TLC) or a quad-level cell (QLC), and the first voltage is a read voltage corresponding to a highest threshold voltage range of the memory cell.

5. The memory device according to claim 4, wherein the memory cell is a TLC, the first effective read voltage comprises the first voltage, the plurality of effective read voltages comprise a second effective read voltage lower than the first voltage and a third effective read voltage higher than the first voltage, and selecting the first piece of data comprises:
in response to determining that the total number of first memory cells is smaller than a first threshold of the one or more thresholds, selecting, as the first piece of data, a piece of the estimated data corresponding to the second effective read voltage, wherein the first threshold is smaller than one-eighth of a total number of all memory cells in the memory cell array;
in response to determining that the total number of first memory cells is larger than a second threshold of the one or more thresholds, selecting, as the first piece of data, a piece of the estimated data corresponding to the third effective read voltage, wherein the second threshold is larger than one-eighth of the total number of all memory cells in the memory cell array; or
in response to determining that the total number of first memory cells is larger than the first threshold and smaller than the second threshold, selecting, as the first piece of data, a piece of the estimated data corresponding to the first voltage.

6. The memory device according to claim 5, wherein the first threshold is smaller than the second threshold.

7. The memory device according to claim 3, wherein the first effective read voltage is smaller than the first voltage, the threshold voltage of each of the first memory cells is smaller than the first voltage, the plurality of effective read voltages further comprise the first voltage and a second effective read voltage larger than the first voltage, and selecting the first piece of data comprises:
in response to determining that the total number of first memory cells is smaller than a third threshold of the one or more thresholds, selecting, as the first piece of data, a piece of the estimated data corresponding to the first effective read voltage, wherein the third threshold is a total number of second memory cells in the memory cell array, and a threshold voltage of each of the second memory cells is larger than the first voltage and smaller than the second effective read voltage;
in response to determining that the total number of first memory cells is larger than the third threshold, selecting, as the first piece of data, a piece of the estimated data corresponding to the second effective read voltage; or
in response to determining that the total number of first memory cells is the same as the third threshold, selecting, as the first piece of data, a piece of the estimated data corresponding to the first voltage.

8. The memory device according to claim 3, wherein the first effective read voltage is smaller than the first voltage, the plurality of effective read voltages further comprise the first voltage, the threshold voltage of each of the first memory cells is smaller than the first voltage and is larger than the first effective read voltage, and selecting the first piece of data comprises:
in response to determining that the total number of first memory cells is smaller than a fourth threshold of the one or more thresholds, selecting, as the first piece of data, a piece of the estimated data corresponding to the first voltage; or
in response to determining that the total number of first memory cells is larger than the fourth threshold, selecting, as the first piece of data, a piece of the estimated data corresponding to the first effective read voltage.

9. The memory device according to claim 1, wherein sensing the voltages of the bit line at the plurality of time instances comprises a three-strobe sensing, and the three-strobe sensing comprises:
sensing, at a first time instance of the plurality of time instances and as a first sensed voltage, the voltages of the bit line;
sensing, at a second time instance of the plurality of time instances and as a second sensed voltage, the voltages of the bit line, wherein the second sensed voltage is lower than the first sensed voltage; and
sensing, at a third time instance of the plurality of time instances and as a third sensed voltage, the voltages of the bit line, wherein the third sensed voltage is lower than the second sensed voltage.

10. The memory device according to claim 1, wherein the read operation is a default read operation performed after a beginning of life (BOL) phase of the memory cell or an end of life (EOL) phase of the memory cell.

11. The memory device according to claim 1, wherein the read operation comprises a first read operation of the memory cell and a second read operation of the memory cell, the first read operation comprises selecting the first piece of data, the second read operation comprises selecting a second piece of data, and the read operation further comprises outputting data stored in the memory cell based on the first piece of data and the second piece of data.

12. A method, comprising:
during a read operation of a memory cell in a memory cell array:
applying a first voltage of a plurality of voltages to a word line coupled to the memory cell;
sensing voltages of a bit line coupled to the memory cell at a plurality of time instances;
obtaining, based on the voltages of the bit line, a plurality of pieces of estimated data of the memory cell corresponding to the plurality of time instances; and
selecting a first piece of data corresponding to the first voltage from the plurality of pieces of estimated data.

13. The method according to claim 12, wherein selecting the first piece of data corresponding to the first voltage from the plurality of pieces of estimated data comprises:
determining a total number of first memory cells in the memory cell array; and
selecting, based on a comparison of the total number of first memory cells to one or more thresholds, the first piece of data corresponding to the first voltage from the plurality of pieces of estimated data.

14. The method according to claim 13, wherein a threshold voltage of each of the first memory cells is larger than a first effective read voltage of a plurality of effective read voltages of the memory cell, and wherein the plurality of pieces of estimated data correspond to the plurality of effective read voltages of the memory cell.

15. The method according to claim 14, wherein the memory cell is a triple-level cell (TLC) or a quad-level cell (QLC), and the first voltage is a read voltage corresponding to a highest threshold voltage range of the memory cell.

16. The method according to claim 15, wherein the memory cell is a TLC, the first effective read voltage comprises the first voltage, the plurality of effective read voltages comprise a second effective read voltage lower than the first voltage and a third effective read voltage higher than the first voltage, and selecting the first piece of data comprises:
in response to determining that the total number of first memory cells is smaller than a first threshold of the one or more thresholds, selecting, as the first piece of data, a piece of the estimated data corresponding to the second effective read voltage, wherein the first threshold is smaller than one-eighth of a total number of all memory cells in the memory cell array;
in response to determining that the total number of first memory cells is larger than a second threshold of the one or more thresholds, selecting, as the first piece of data, a piece of the estimated data corresponding to the third effective read voltage, wherein the second threshold is larger than one-eighth of the total number of all memory cells in the memory cell array; or
in response to determining that the total number of first memory cells is larger than the first threshold and smaller than the second threshold, selecting, as the first piece of data, a piece of the estimated data corresponding to the first voltage.

17. The method according to claim 16, wherein the first threshold is smaller than the second threshold.

18. The method according to claim 14, wherein the first effective read voltage is smaller than the first voltage, the threshold voltage of each of the first memory cells is smaller than the first voltage, the plurality of effective read voltages further comprise the first voltage and a second effective read voltage larger than the first voltage, and selecting the first piece of data comprises:
in response to determining that the total number of first memory cells is smaller than a third threshold of the one or more thresholds, selecting, as the first piece of data, a piece of the estimated data corresponding to the first effective read voltage, wherein the third threshold is a total number of second memory cells in the memory cell array, and a threshold voltage of each of the second memory cells is larger than the first voltage and smaller than the second effective read voltage;
in response to determining that the total number of first memory cells is larger than the third threshold, selecting, as the first piece of data, a piece of the estimated data corresponding to the second effective read voltage; or
in response to determining that the total number of first memory cells is the same as the third threshold, selecting, as the first piece of data, a piece of the estimated data corresponding to the first voltage.

19. The method according to claim 14, wherein the first effective read voltage is smaller than the first voltage, the plurality of effective read voltages further comprise the first voltage, the threshold voltage of each of the first memory cells is smaller than the first voltage and is larger than the first effective read voltage, and selecting the first piece of data comprises:
in response to determining that the total number of first memory cells is smaller than a fourth threshold of the one or more thresholds, selecting, as the first piece of data, a piece of the estimated data corresponding to the first voltage; or
in response to determining that the total number of first memory cells is larger than the fourth threshold, selecting, as the first piece of data, a piece of the estimated data corresponding to the first effective read voltage.

20. A memory system, comprising:
a memory device, comprising:
a memory cell array; and
a peripheral circuit coupled to the memory cell array and configured to perform operations comprising:
during a read operation of a memory cell in the memory cell array:
applying a first voltage of a plurality of voltages to a word line coupled to the memory cell;
sensing voltages of a bit line coupled to the memory cell at a plurality of time instances;
obtaining, based on the voltages of the bit line, a plurality of pieces of estimated data of the memory cell corresponding to the plurality of time instances; and
selecting a first piece of data corresponding to the first voltage from the plurality of pieces of estimated data; and
a controller coupled to the memory device and configured to send one or more signals to the memory device to initiate the operations.
